(19) United States
(12) Patent Application Publication
(10) Pub. No.: US 2025/0338645 A1
(43) Pub. Date: Oct. 30, 2025

(54) STRUCTURE WITH DOPED WELL BETWEEN PHOTODETECTOR AND OPTICAL INTERFACE OF SEMICONDUCTOR LAYER

(71) Applicant: GlobalFoundries U.S. Inc., Malta, NY (US)

(72) Inventors: John J. Ellis-Monaghan, Grand Isle, VT (US); Ramsey M. Hazbun, Colchester, VT (US); Rajendran Krishnasamy, Essex Junction, VT (US); Vinit Dhulla, Round Rock, TX (US); Zhong-Xiang He, Essex Junction, VT (US); Siva P. Adusumilli, Rio Rancho, NM (US)

(21) Appl. No.: 18/648,553

(22) Filed: Apr. 29, 2024

(51) Int. Cl. H01L 27/146

(52) U.S. Cl. CPC H10F 39/8033; H10F 39/184; H10F 39/8063; H10F 39/807

(57) ABSTRACT

The disclosure provides a structure with a doped well between a photodetector and an optical interface of a semiconductor layer. A structure of the disclosure includes a semiconductor layer having a first surface configured for optically interfacing with incident radiation, and a second surface opposite the first surface. A photodetector is within the semiconductor layer and on the second surface thereof. A doped well is within the semiconductor layer between the photodetector and the first surface. The doped well has a same conductivity type as the semiconductor layer and a higher dopant concentration than the semiconductor layer.

### BACKGROUND

The present disclosure relates to photodetectors.

Photodetectors convert optical signals into electrical signals when photon radiation alters the electrical characteristics of the photodetectors. This operation is suitable for image sensors used in, for example, data communications devices. One issue that arises is that photodetectors that use silicon alone are generally limited to use within specific radiation wavelengths (e.g., between 190 nm and 1100 nm).

Image sensors may include frontside illuminated and backside illuminated devices, referring to the orientation of incident radiation relative to the device. Backside illuminated devices, which may be effective for detecting infrared wavelengths, may need to undergo significant processing to avoid “dark currents.” Dark currents are electrically generated at the photodetector from non-radiation sources. Such processing may include plasma boron and/or metal oxide doping at the surface of the device. These processes are expensive and difficult to implement for certain types of devices.

### SUMMARY

Embodiments of the disclosure provide a structure including: a semiconductor layer having a first surface configured for optically interfacing with incident radiation, and a second surface opposite the first surface; a photodetector within the semiconductor layer and on the second surface thereof; and a doped well within the semiconductor layer between the photodetector and the first surface, the doped well having a same conductivity type as the semiconductor layer and a higher dopant concentration than the semiconductor layer.

Other embodiments of the disclosure provide a structure including: a semiconductor layer having a first surface configured for optically interfacing with incident radiation, and a second surface opposite the first surface; a photodetector within the semiconductor layer and on the second surface thereof; and a doped well within the semiconductor layer between the photodetector and the first surface, the doped well having a same conductivity type as the semiconductor layer and a higher dopant concentration than the semiconductor layer, wherein a first portion of the semiconductor layer is between the doped well and the first surface of the semiconductor layer, and a second portion of the semiconductor layer is between the doped well and the photodetector.

Additional embodiments of the disclosure provide a structure including: a semiconductor layer having a first surface configured for optically interfacing with incident radiation, and a second surface opposite the first surface; a photodetector within the semiconductor layer and on the second surface thereof; and a doped well within the semiconductor layer between the photodetector and the first surface, the doped well having a same conductivity type as the semiconductor layer and a higher dopant concentration than the semiconductor layer, wherein a surface of the doped well is coincident with the first surface of the semiconductor layer.

### BRIEF DESCRIPTION OF THE DRAWINGS

The embodiments herein will be better understood from the following detailed description with reference to the drawings, which are not necessarily drawn to scale and in which:

FIG. 1 provides a cross-sectional view of a structure according to embodiments of the disclosure.

FIG. 2 provides a cross-sectional view of a structure according to further embodiments of the disclosure.

FIG. 3 provides a cross-sectional view of a structure according to additional embodiments of the disclosure.

FIG. 4 provides a cross-sectional view of a structure according to still further embodiments of the disclosure.

FIG. 5 provides a cross-sectional view of a structure with multiple photodetectors according to embodiments of the disclosure.

### DETAILED DESCRIPTION

As noted above, image sensors may include frontside illuminated and backside illuminated devices, referring to the orientation of incident radiation relative to the device. Backside illuminated devices may need to undergo significant processing to avoid “dark currents,” i.e., currents generated at the photodetector when no radiation is transmitted thereto. Such processing may include plasma boron and/or metal oxide doping at the surface of the device. These processes are expensive and difficult to implement for certain types of devices.

In view of these and other issues, the disclosure provides a structure with a doped well between a photodetector and an optical interface of a semiconductor layer. A structure of the disclosure includes a semiconductor layer having a first surface configured for optically interfacing with incident radiation, and a second surface opposite the first surface. A photodetector is within the semiconductor layer and on the second surface thereof. A doped well is within the semiconductor layer between the photodetector and the first surface. The doped well has a same conductivity type as the semiconductor layer and a higher dopant concentration than the semiconductor layer.

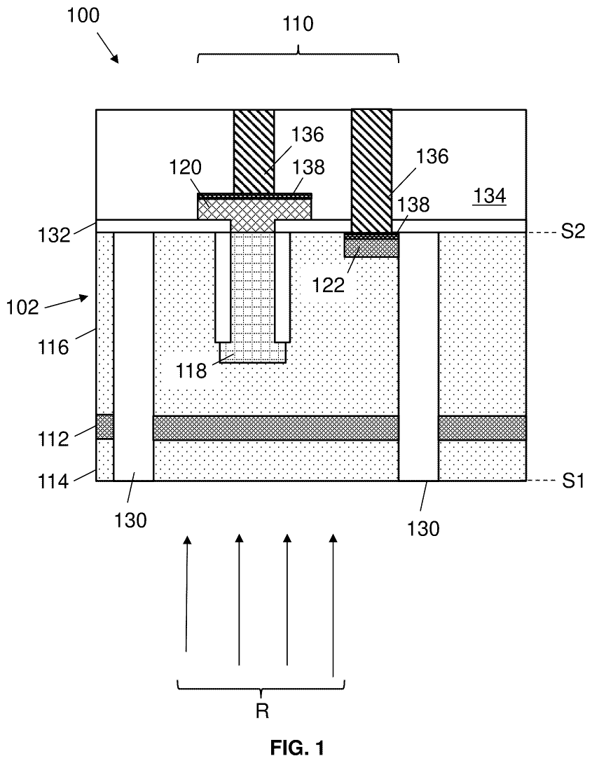

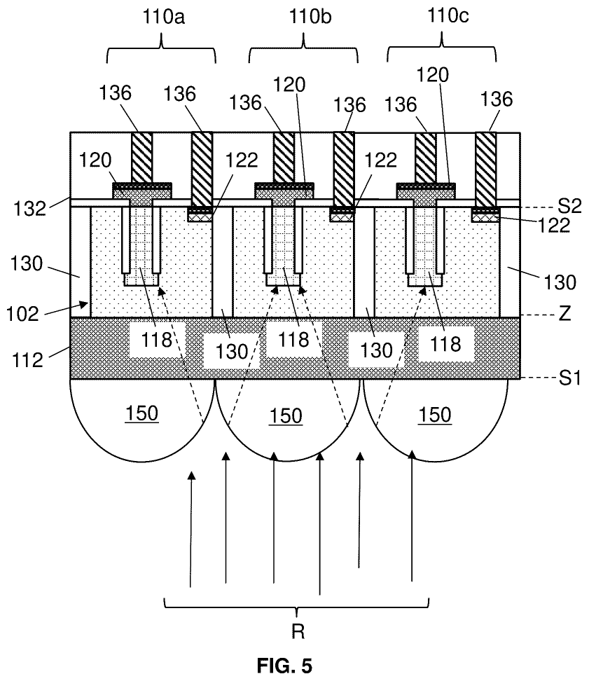

FIG. 1 illustrates a structure 100 according to embodiments of the disclosure. As shown, structure 100 includes a semiconductor layer 102, e.g., one or more semiconductor materials. Semiconductor layer 102 may include but is not limited to silicon, germanium, silicon germanium, silicon carbide, or any other currently known or later developed semiconductor layers. A portion or entire semiconductor layer 102 may be strained. Semiconductor layer 102 also may have a particular conductivity type, e.g., p-type doping. Semiconductor layer 102 may have a first surface S1 configured for optically interfacing with incident radiation R, and a second surface S2 opposite first surface S1. Thus, first surface S1 may be considered to be an “optical interface” of structure 100 and/or semiconductor layer 102, even when focusing elements (e.g., focusing lens(es) 150 (FIG. 5)) or other components are positioned thereon. As discussed in further detail herein, a photodetector 110 (e.g., an infrared detector and/or other structure for producing electric current in response to light and/or various types of radiation) may be on semiconductor layer 102. Photodetector 110 may be on second surface S2 and/or within portions of semiconductor layer 102. Semiconductor layer 102 may extend horizontally beyond the cross-section illustrated in FIG. 1.

Semiconductor layer 102 may have a doped well 112 therein. Doped well 112 may include dopants of the same conductivity type as semiconductor layer 102 but in a higher concentration. Doped well 112 may include p-type dopants formed using any now known or later developed technique (e.g., in-situ doping or ion implantation). Doped well 112 may be formed within semiconductor layer 102 before any isolation materials (e.g., shallow and/or deep trench isolations (TIs), insulator layers, etc.) are also formed therein. Thus, doped well 112 may have a substantially uniform thickness and position within semiconductor layer 102. Doped well 112 may have any desired thickness. In various embodiments, doped well 112 may have a thickness of between approximately one-hundred and approximately one-thousand nanometers (nm) within semiconductor layer 102. Although doped well 112 is shown to be vertically distal to surfaces S1, S2 of semiconductor layer 102, further embodiments of structure 100 discussed herein may include doped well 112 coincident with first surface S1, and/or doped wells 112 with a vertical thickness larger than one-thousand nanometers.

In embodiments where doped well 112 is vertically distal to first surface S1 of semiconductor layer 102, a first portion 114 of semiconductor layer 102 may be vertically between doped well 112 and first surface S1, and a second portion 116 of semiconductor layer 102 may be vertically between doped well 112 and second surface S2. First portion 114 and second portion 116 do not need to be of similar vertical thickness. Doped well 112 may have the same conductivity type as portions 114, 116, e.g., p-type doping. However, doped well 112 may have relatively high p-type (“P+”) doping (e.g., doping sufficient to produce a resistivity of less than approximately one Ohm-centimeter in doped well 112) whereas portions 114, 116 may have significantly lower p-type doping. Second portion 116 may include at least some components of photodetector 110 therein, such that photodetector 110 is on second surface S2 of semiconductor layer 102 and within a part of second portion 116, over doped well 112. In addition, as discussed herein, second portion 116 of semiconductor layer 102 may provide active semiconductor material for interconnecting various parts of photodetector 110.

In the configuration shown, photodetector 110 of structure 100 may be a “PIN” photodetector structure, e.g., for detecting incident radiation R (such as infrared light). In the context of photodetector 110, the term “PIN” refers to a photodetector configuration with two regions having different types of conductivity (i.e., P-type and N-type), which may be induced through dopants within the two regions, which are separated by an intrinsic region having a substantially lower amount of dopants therein. In some cases, the intrinsic region may have substantially no doping therein. In the example of structure 100, second portion 116 itself may be considered an “intrinsic region,” despite having p-type doping, as its dopant concentration may be substantially lower than other components of photodetector 110. During operation, the intrinsic region (e.g., second portion 116 where electrically coupled to other components of photodetector 110) functions as an “absorption region,” in that most incoming radiation R is absorbed in the semiconductor material of second portion 116, and thus charge carriers are generated therein and contribute to the photocurrent between two terminals of photodetector 110.

To provide the cathode terminal of photodetector 110, structure 100 may include a detector absorption layer 118 (e.g., germanium (Ge)) within semiconductor layer 102 (e.g., within second portion 116), distal to doped well 112. Detector absorption layer 118 may be formed, e.g., by removing a portion of semiconductor layer 102 from second surface S2 and forming a detector absorption material therein (e.g., by deposition, epitaxial growth, etc., where applicable). Photodetector 110 and semiconductor layer 102 may have different compositions, e.g., detector absorption layer 118 of photodetector 110 may include Ge whereas semiconductor layer 102 may include silicon (Si). During operation, these differences in material composition may prevent charge carriers from being lost in the doped semiconductor material of doped well 112, and instead allow such carriers to be collected within photodetector 110. The combination of Ge in photodetector 110 and Si in semiconductor layer 102 is operable with structure 100 because Ge is sensitive to infrared radiation whereas Si is not sensitive to such radiation. Thus, incoming photons from incident radiation R will not be absorbed until they reach detector absorption layer 118. Other combinations of materials are also possible. For example, where semiconductor layer 102 includes Si, photodetector 110 and detector absorption layer 118 thereof may include indium phosphide (InP), mercury cadmium telluride (HgCdTe), and/or similar materials. In other cases, semiconductor layer 102 may include silicon carbide (SiC), in which case photodetector 110 and detector absorption layer 118 thereof may include Si because Si has a higher optical absorption than SiC. Any combination of materials where photodetector 110 and semiconductor layer 102 have different optical absorption characteristics such that semiconductor layer 102 does not absorb the wavelength(s) of interest but photodetector 110 does absorb such wavelengths is contemplated.

The physical interface between detector absorption layer 118 and semiconductor layer 102 will cause photons to be absorbed from incident radiation R, thus causing electric currents to be generated in response to incident radiation R. Photodetector 110 can include a cathode 120 on detector absorption layer 118, and optionally above semiconductor layer 102 (e.g., over second surface S2 thereof). In other implementations, cathode 120 may be wholly or partially within semiconductor layer 102. Cathode 120 may include a semiconductor material having an opposite conductivity type from semiconductor layer 102, and optionally, may have an opposite conductivity type from doped well 112. According to an example, cathode 120 may include polycrystalline silicon (poly-Si) or other polycrystalline semiconductor materials that are highly doped relative to semiconductor layer 102. In a more specific example, cathode 120 may be N+ doped polysilicon (poly-Si). Regardless of composition, cathode 120 may be on detector absorption layer 118 such that cathode 120 physically interfaces with detector absorption layer 118 and thus provides an electrical coupling therebetween.

Photodetector 110 also includes an anode 122 on or within semiconductor layer 102. In an example, photodetector 110 is within second portion 116 of semiconductor layer 102 such that an upper surface of anode 122 is coincident with second surface S2, but this is not necessarily required. Anode 122 may have the same doping type as semiconductor layer 102 and/or doped well 112, e.g., it also may be doped p-type in the case where semiconductor layer 102 and doped well 112 are doped p-type. In some implementations, anode 122 may be highly doped p-type (“P+ doping”) for better electrical coupling to other portions of photodetector 110. Anode 122 may be formed, e.g., by subjecting targeted areas of semiconductor layer 102 to doping (e.g., ion implantation, in situ doping, etc., as discussed herein), and/or by removing portions of semiconductor layer 102 and replacing them with other semiconductor materials having a desired conductivity type and/or dopant concentration. Anode 122 may be horizontally distal to detector absorption layer 118, and thus is also distal to cathode 120 thereover. Portions of semiconductor layer 102 physically separate anode 122 from detector absorption layer 118. Within photodetector 110, cathode 120 and anode 122 are intercoupled through semiconductor layer 102 and detector absorption layer 118, thereby allowing incident radiation R to produce electric current between cathode 120 and anode 122 as incoming photons are absorbed within semiconductor layer 102 and detector absorption layer 118.

Structure 100 may include one or more isolation layers 130 (also known as trench isolations or “TIs” in some implementations) within semiconductor layer 102. Each isolation layer 130 may include, e.g., an insulating material such as oxide, insulative semiconductor, etc., with a composition operable for isolating some portions of semiconductor layer 102 and/or photodetector 110 from other areas of a device. Isolation layers 130, although shown in two locations in the cross-section of FIG. 1, may extend around a circumference of photodetector 110. Doped well 112 may extend horizontally between interior sidewalls of isolation layer(s) 130, such that the surface area of doped well 112 is larger than photodetector 110. Thus, outer portions of doped well 112 and isolation layers 130 are horizontally outside photodetector 110. Structure 100 also may include an insulator layer 132 over semiconductor layer 102, e.g., for vertically electrically isolating active portions of semiconductor layer 102 and photodetector 110 from various wires and/or components in overlying layers of a device. Some portions of insulator layer 132 may extend vertically into semiconductor layer 102 alongside detector absorption layer 118, e.g., to limit the physical interface between detector absorption layer 118 and semiconductor layer 102. To provide this configuration, a portion of semiconductor layer 102 may be removed to form a trench, insulator layer 132 may be formed within sidewalls of the trench and on semiconductor layer 102, any portions of insulator layer 132 may be removed from the bottom of the trench by directional etching, and detector absorption layer 118 thereafter can be formed within the trench. Insulator layer 132 may be formed of, e.g., any now known or later developed insulative material such as but not limited to oxides. Insulator layer 132 may be formed using deposition and/or any other technique to form a material on semiconductor layer 102.

For purposes herein, an “insulator” is a relative term that means a material or structure that allows substantially less (<95%) electrical current to flow than does a “conductor.” The dielectrics (insulators) mentioned herein can, for example, be grown from either a dry oxygen ambient or steam and then patterned. Alternatively, the dielectrics herein may be formed (grown or deposited) from any of the many candidate low dielectric constant materials (low-K (where K corresponds to the dielectric constant of silicon dioxide) materials such as fluorine or carbon-doped silicon dioxide, porous silicon dioxide, porous carbon-doped silicon dioxide, spin-on silicon or organic polymeric dielectrics, etc.) or high dielectric constant (high-K) materials, including but not limited to silicon nitride, silicon oxynitride, a gate dielectric stack of SiO₂ and Si₃N₄, hafnium oxide (HfO₂), hafnium zirconium oxide (HfZrO₂), zirconium dioxide (ZrO₂), hafnium silicon oxynitride (HfSiON), hafnium aluminum oxide compounds (HfAlOₓ), other metal oxides like tantalum oxide, etc. The thickness of insulators herein may vary, contingent upon desired device performance.

Structure 100 may include an inter-level dielectric (ILD) layer 134 over insulator layer 132, cathode 120, and any other components thereunder. ILD layer 134 may include the same insulating material as isolation layer 130 and/or insulator layer 132 or may include a different electrically insulative material for vertically separating active materials from overlying materials, e.g., various horizontally extending wires or vias. ILD layer 134, insulator layer 132, and dielectric layer(s) 130 nonetheless constitute different components, e.g., based on the composition of their adjacent components and/or functions within structure 100. ILD layer 134 may be formed by deposition and/or other techniques to provide electrically insulating materials, and can then be planarized (e.g., using CMP), such that its upper surface remains above any active components of structure 100.

A set of contacts 136 through ILD layer 134 may vertically couple cathode 120 and anode 122 and overlying metal wires and/or vias. Some portions of cathode 120 and/or anode 122 can be converted to a silicide layer 138 to improve conductivity between each contact 136 and cathode 120 or anode 122 thereunder, e.g., by providing a conductive metal alloy including conductors such as such as cobalt (Co), titanium (Ti), nickel (Ni), platinum (Pt), or similar material on the upper surface(s) of a targeted material. The conductive material(s) may be annealed while in contact with the underlying semiconductor(s) to produce silicide layer 138 for electrically coupling cathode 120, and/or anode 122 materials to any contacts formed thereon. Excess conductive material can then be removed using any now known or later developed solution, e.g., etching, planarization, etc.

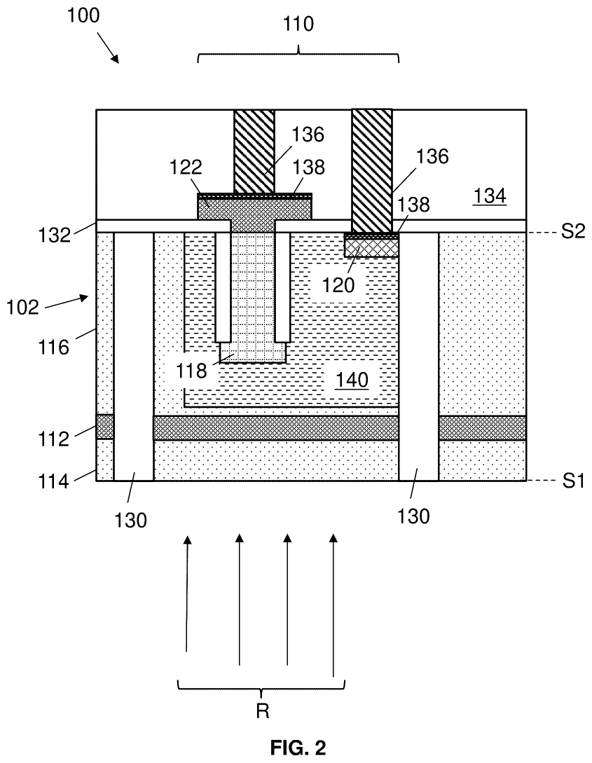

Turning to FIG. 2, embodiments of structure 100 may be operable for use with opposite polarity configurations of photodetector 110. Specifically, photodetector 110 may have cathode 120 and anode 122 in opposite positions. That is, cathode 120 still may have n-type conductivity (e.g., “N+” doping) but may be within semiconductor layer 102 in a location horizontally distal to detector absorption layer 118. Anode 122 may still have p-type conductivity (e.g., it may include “P+” doped polysilicon) but may be located on detector absorption layer 118 and above semiconductor layer 102. In such a configuration, some parts of second portion 116 of semiconductor layer 102 will have the same doping type as cathode 120 to provide a PIN doping profile for photodetector 110. Thus, structure 100 may include a shallow well 140 with the same conductivity type as cathode 120, but with a much lower dopant concentration to provide an intrinsic region operable to absorb most incoming radiation R via its interface with detector absorption layer 118. Thus, charge carriers are generated in shallow well 140 via its structural interface with detector absorption layer 118. Shallow well 140 thus allows photocurrents to be generated between cathode 120 and anode 122 of photodetector 110 even though its conductivity type is different from other parts of semiconductor layer 102. Structure 100 otherwise may be similar or identical to other implementations discussed herein. Doped well 112 of structure may be between photodetector 110 and first surface S1 and may have a different conductivity type from shallow well 140. According to an example, doped well 112 may have the same conductivity type as semiconductor layer 102 but in a higher doping concentration. More specifically, semiconductor layer 102 may have light amounts of p-type doping and doped well 112 may have P+ doping even where shallow well 140 has n-type doping.

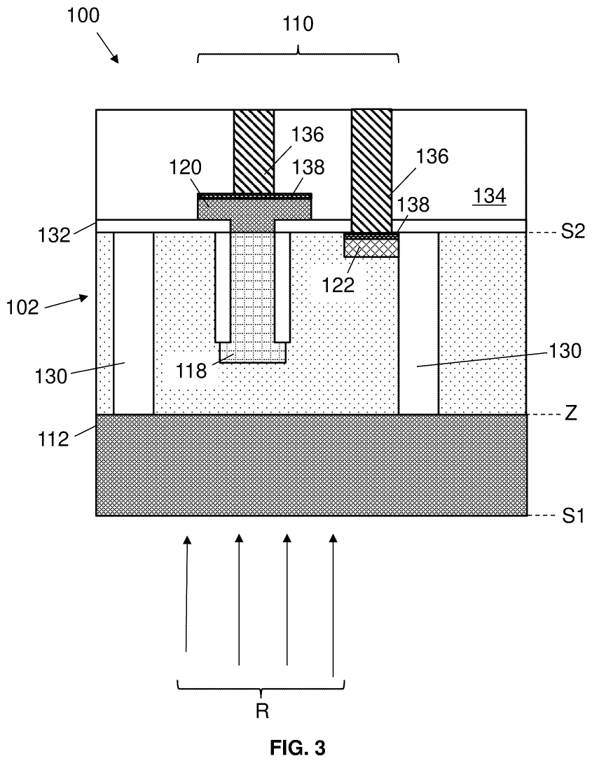

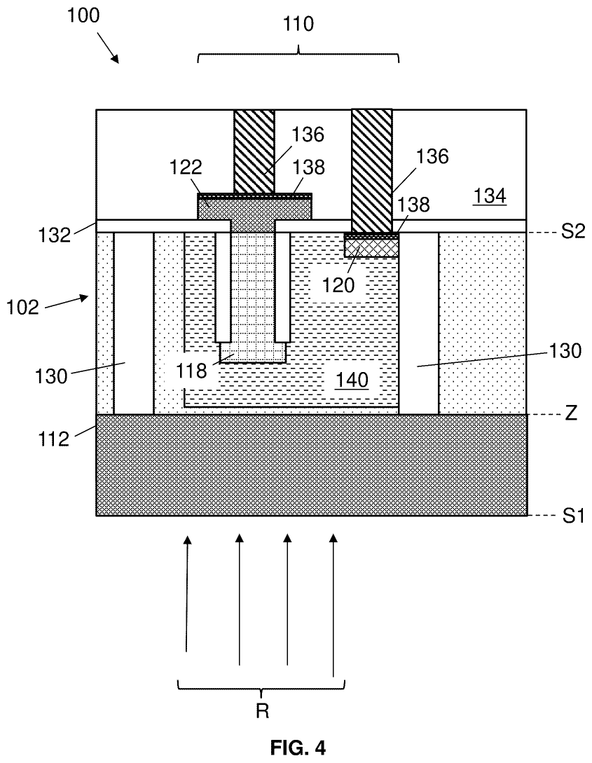

FIGS. 3 and 4 depict further implementations of structure 100 in which doped well 112 is coincident with first surface S1 of semiconductor layer 102, and thus may have a larger vertical thickness than in other implementations of structure 100. Here, doped well 112 may be large enough such that first portion 114 (FIGS. 1, 2) of semiconductor layer 102 is not present or otherwise of negligible size. Otherwise, the device of FIG. 3 is similar to that of FIG. 1, and the device of FIG. 4 is similar to that of FIG. 2. Doped well 112 during operating may serve the same function as other embodiments of structure 100, i.e., it is below detector absorption layer 118 and prevents carriers generated at first surface S1 from sources other than radiation R from diffusing into cathode 120 or anode 122 to produce dark currents. In this configuration, an upper surface Z of doped well 112 may intersect lower surfaces of isolation layers 130. Doped well 112 thereby extends horizontally beyond the outer perimeter(s) of isolation layers 130 and optionally may extend continuously through semiconductor layer 102, beneath other devices (not shown) therein. In this case, doped well 112 may have a thickness of at least approximately one-thousand nanometers or more. Regardless of the shape and size of doped well 112, structure 100 otherwise may be structurally similar or identical to other embodiments of structure 100. Thus, FIGS. 3 and 4 depict photodetector 110 with two different polarities being above doped well 112 and doped well 112 having a lower surface that is coincident with first surface S1 of semiconductor layer 102. Despite the larger thickness of doped well 112 compared to other implementations, incident radiation R will still pass through doped well 112, enabling semiconductor layer 102 and/or shallow well 140 to capture incoming photons and thus produce photocurrents in photodetector 110.

Turning to FIG. 5, embodiments of structure 100 may be implemented at scale and in conjunction with other components to aid in capturing incident radiation R. In the configuration shown, three photodetectors 110 (separately labeled 110a, 110b, 110c) are provided. Isolation layers 130 may be horizontally between each photodetector 110a, 110b, 110c in semiconductor layer 102 to electrically isolate photodetectors 110 from each other. Each photodetector 110 may be vertically aligned with one or more focusing lenses 150. Each focusing lens 150 may be mounted on and/or coupled to first surface S1 such that incident radiation R passes through focusing lenses 150 before entering semiconductor layer 102. Focusing lenses 150 may have convex exteriors for directing incident radiation R toward detector absorption layers 118 of photodiode(s) 110a, 110b, 110c aligned therewith. Example pathways of photons from each focusing lens 150 toward photodiode(s) 110a, 110b, 110c are depicted in FIG. 5. During operation, incident radiation R arriving at structure 100 from the backside of a device (e.g., first surface S1 of semiconductor layer 102) may pass through a corresponding focusing lens 150 toward a particular photodetector 110. Each photodetector 110a, 110b, 110c, etc., may define one pixel of a larger array of photodetectors 110 for detecting incoming radiation R in structure 100. Focusing lenses 150 thus may prevent incident radiation R from being misaligned with active areas of certain photodetectors 110, whereas doped well 112 prevents other sources of incoming energy from triggering dark currents in each photodetector 110. Thus, doped well 112 and focusing lenses 150 may be interoperable to ensure that more incident radiation R is detected without also triggering photocurrents from sources other than incident radiation R. It is also understood that the polarity of one or more photodetectors 110a, 110b, 110c may be reversed through modifications discussed elsewhere herein, e.g., switching the location of cathode 120 and anode 122 and providing shallow well 140 (FIGS. 3, 4) within semiconductor layer 102. In still further embodiments, deep wells 112 of smaller vertical thickness (e.g., as shown elsewhere herein in FIGS. 1 and 2) also may be used together with multiple photodetectors 110a, 110b, 110c and/or focusing lenses 150.

Embodiments of the disclosure provide various technical and commercial advantages, examples of which are discussed herein. Embodiments of structure 100 are operable to reduce or eliminate the occurrence of dark currents in photodiode(s) 110, i.e., photocurrents triggered by energy sources other than photons. Doped well 112 beneath photodiode(s) 110 creates a region of buffer material that impedes or blocks charge carriers from sources other than incident radiation R from passing to active materials of photodiode(s) 110, e.g., second portion(s) 116 and/or detector absorption layer(s) 118 which may together define the intrinsic region of a PIN photodiode structure (e.g., photodetector 110). Embodiments of the disclosure avoid more complicated types of backside processing, e.g., deep boron implantations, epitaxial growth of similarly doped materials, and/or the use of less readily available substrate compositions.

The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as tungsten, hafnium, tantalum, molybdenum, titanium, or nickel, or a metal silicide, any alloys of such metals, and may be deposited using physical vapor deposition, chemical vapor deposition, or any other technique known in the art.

There are various types of transistors, which have slight differences in how they are used in a circuit. For example, a bipolar transistor has terminals labeled base, collector, and emitter. A small current at the base terminal (that is, flowing between the base and the emitter) can control, or switch, a much larger current between the collector and emitter terminals. Another example is a field-effect transistor, which has terminals labeled gate, source, and drain. A voltage at the gate can control a current between source and drain. Within such transistors, a semiconductor (channel region) is positioned between the conductive source region and the similarly conductive drain (or conductive source/emitter regions), and when the semiconductor is in a conductive state, the semiconductor allows electrical current to flow between the source and drain, or collector and emitter. The gate is a conductive element that is electrically separated from the semiconductor by a “gate oxide” (which is an insulator); and current/voltage within the gate changes makes the channel region conductive, allowing electrical current to flow between the source and drain. Similarly, current flowing between the base and the emitter makes the semiconductor conductive, allowing current to flow between the collector and emitter.

The terminology used herein is for the purpose of describing particular embodiments only and is not intended to be limiting of the foregoing. As used herein, the singular forms “a,” “an,” and “the” are intended to include the plural forms as well, unless the context clearly indicates otherwise. Furthermore, as used herein, terms such as “right”, “left”, “vertical”, “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element.

Embodiments herein may be used in a variety of electronic applications, including but not limited to advanced sensors, memory/data storage, semiconductors, microprocessors and other applications. A resulting device and structure, such as an integrated circuit (IC) chip can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The elements herein can be modified to incorporate any number of variations, alterations, substitutions, or equivalent arrangements not heretofore described, but which are commensurate with the spirit and scope herein. Additionally, while various embodiments have been described, it is to be understood that aspects herein may be included by only some of the described embodiments. Accordingly, the claims below are not to be seen as limited by the foregoing description. All structural and functional equivalents to the elements of the various embodiments described throughout this disclosure that are known or later, come to be known, to those of ordinary skill in the art are expressly incorporated herein by reference and intended to be encompassed by this disclosure. It is therefore to be understood that changes may be made in the particular embodiments disclosed which are within the scope of the foregoing as outlined by the appended claims.

What is claimed is:

1. A structure comprising:
a semiconductor layer having a first surface configured for optically interfacing with incident radiation, and a second surface opposite the first surface;
a photodetector within the semiconductor layer and on the second surface thereof; and
a doped well within the semiconductor layer between the photodetector and the first surface, the doped well having a same conductivity type as the semiconductor layer and a higher dopant concentration than the semiconductor layer.

2. The structure of claim 1, wherein a surface area of the doped well is larger than a surface area of the photodetector.

3. The structure of claim 1, wherein a first portion of the semiconductor layer is between the doped well and the first surface, and a second portion of the semiconductor layer is between the doped well and the photodetector.

4. The structure of claim 1, wherein the doped well includes a first surface opposite the first surface of the semiconductor layer and distal to the photodetector, and a second surface coincident with the first surface of the semiconductor layer.

5. The structure of claim 1, wherein the semiconductor layer is a first p-type doping concentration, and the doped well has a second P+ doping concentration higher than the first p-type doping concentration.

6. The structure of claim 1, wherein the photodetector includes:
a detector absorption layer within the semiconductor layer and distal to the doped well;
a cathode on the detector absorption layer and the second surface of the semiconductor layer; and
an anode on the semiconductor layer horizontally distal to the detector absorption layer.

7. The structure of claim 1, wherein a material composition of the semiconductor layer is different from a material composition of the photodetector.

8. A structure comprising:
a semiconductor layer having a first surface configured for optically interfacing with incident radiation, and a second surface opposite the first surface;
a photodetector within the semiconductor layer and on the second surface thereof; and
a doped well within the semiconductor layer between the photodetector and the first surface, the doped well having a same conductivity type as the semiconductor layer and a higher dopant concentration than the semiconductor layer,
wherein a first portion of the semiconductor layer is between the doped well and the first surface of the semiconductor layer, and a second portion of the semiconductor layer is between the doped well and the photodetector.

9. The structure of claim 8, wherein a surface area of the doped well is larger than a surface area of the photodetector.

10. The structure of claim 8, further comprising a dielectric layer horizontally surrounding the photodetector and the doped well.

11. The structure of claim 8, wherein the semiconductor layer has a p-type doping concentration, and the doped well has a P+ doping concentration.

12. The structure of claim 8, wherein the photodetector includes:
a detector absorption layer within the semiconductor layer and distal to the doped well;
a cathode on the detector absorption layer and the second surface of the semiconductor layer; and
an anode on the semiconductor layer horizontally distal to the detector absorption layer.

13. The structure of claim 12, wherein the photodetector further includes an n-type shallow well within the semiconductor layer between the detector absorption layer and the cathode, wherein a p-type doped portion of the semiconductor layer is vertically between the photodetector and the doped well.

14. The structure of claim 8, wherein a material composition of the semiconductor layer includes silicon (Si) and a material composition of the photodetector includes germanium (Ge).

15. A structure comprising:
a semiconductor layer having a first surface configured for optically interfacing with incident radiation, and a second surface opposite the first surface;
a photodetector within the semiconductor layer and on the second surface thereof; and
a doped well within the semiconductor layer between the photodetector and the first surface, the doped well having a same conductivity type as the semiconductor layer and a higher dopant concentration than the semiconductor layer, wherein a surface of the doped well is coincident with the first surface of the semiconductor layer.

16. The structure of claim 15, wherein a material composition of the semiconductor layer is different from a material composition of the photodetector.

17. The structure of claim 15, wherein the semiconductor layer has a first p-type doping concentration, and the doped well has a second P+ doping concentration higher than the first p-type doping concentration.

18. The structure of claim 15, wherein the photodetector includes:
a detector absorption layer within the semiconductor layer and horizontally distal to the doped well;
a cathode on the detector absorption layer and the second surface of the semiconductor layer; and
an anode on the semiconductor layer distal to the detector absorption layer.

19. The structure of claim 18, wherein the photodetector further includes an n-type shallow well within the semiconductor layer between the detector absorption layer and the cathode, wherein a p-type doped portion of the semiconductor layer is vertically between the photodetector and the doped well.

20. The structure of claim 15, further comprising a set of lenses on the first surface of the semiconductor layer, wherein the photodetector is one of a plurality of photodetectors within the semiconductor layer and on the second surface thereof, and the doped well extends horizontally between the set of lenses and each of the plurality of photodetectors.
